(19) United States
(12) Patent Application Publication
(10) Pub. No.: US 2024/0014343 A1
(43) Pub. Date: Jan. 11, 2024

(54) SOLID-STATE IMAGING ELEMENT, IMAGING DEVICE, AND ELECTRONIC DEVICE

(71) Applicant: SONY SEMICONDUCTOR SOLUTIONS CORPORATION, KANAGAWA (JP)

(72) Inventor: FUMIAKI SANO, KANAGAWA (JP)

(21) Appl. No.: 18/253,203

(22) PCT Filed: Nov. 10, 2021
(86) PCT No.: PCT/JP2021/041271

§ 371 Date: May 16, 2023

(30) Foreign Application Priority Data
Nov. 24, 2020 (JP) 2020-194306

(51) Int. Cl. H01L 31/107; H01L 31/0224; H01L 31/0352

(52) U.S. Cl. CPC H01L 31/107; H01L 31/022408; H01L 31/035281

(57) ABSTRACT

The present disclosure relates to a solid-state imaging element, an imaging device, and an electronic device capable of improving light-receiving sensitivity. An avalanche region is formed by forming a P+ type semiconductor region connected to an anode into an annular structure having a hole at a center portion at a pixel center as seen in an incident direction of incident light, and forming an N+ type semiconductor region connected to a cathode at a subsequent stage as seen in the incident direction of the hole. This may be applied to an avalanche photodiode.

### TECHNICAL FIELD

The present disclosure relates to a solid-state imaging element, an imaging device, and an electronic device, and especially relates to a solid-state imaging element, imaging device, and an electronic device capable of improving light-receiving sensitivity.

### BACKGROUND ART

An image sensor having a signal multiplication pixel structure called a single photon avalanche diode (SPAD) has been proposed.

The image sensor using the SPAD is an image sensor having a structure in which an electronic element is arranged for each pixel, the electronic element that outputs one large electric pulse signal by a multiplication effect due to an electron avalanche when one light particle (hereinafter, photon) is incident on the pixel, and may increase sensitivity related to imaging.

Furthermore, the image sensor using the SPAD is applied to a ToF sensor or the like, thereby implementing highly accurate ranging.

In the image sensor using the SPAD, a technology has been proposed in which electrons generated by photoelectric conversion are collected at the center of a pixel so as to be able to receive light, thereby increasing sensitivity (refer to Patent Document 1).

### CITATION LIST

### Patent Document

Patent Document 1: US Patent Application Publication No. 2020/0028018 Specification

### SUMMARY OF THE INVENTION

### Problems to be Solved by the Invention

However, in the technology disclosed in Patent Document 1, the P− type semiconductor layer and the N− type semiconductor layer are in contact with each other, and there is a limit in miniaturizing the pixel in terms of structure, and there is a limit in improving the light-receiving sensitivity in the miniaturized pixel.

The present disclosure has been achieved in view of such a situation, and an object thereof is to improve the light-receiving sensitivity especially in the image sensor using the SPAD.

### Solutions to Problems

A solid-state imaging element, an imaging device, and an electronic device according to an aspect of the present disclosure are a solid-state imaging element, an imaging device, and an electronic device including an avalanche photodiode including an avalanche region including a semiconductor region of a first polarity connected to an anode, and a semiconductor region of a second polarity connected to a cathode, in which the semiconductor region of the first polarity has an annular structure with a hole at a center portion as seen in an incident direction of incident light, and the semiconductor region of the second polarity is formed at a subsequent stage of a position of the hole of the annular structure in the incident direction of the incident light.

According to an aspect of the present disclosure, an avalanche photodiode including an avalanche region including a semiconductor region of a first polarity connected to an anode, and a semiconductor region of a second polarity connected to a cathode are provided, in which the semiconductor region of the first polarity has an annular structure with a hole at a center portion as seen in an incident direction of incident light, and the semiconductor region of the second polarity is formed at a subsequent stage of a position of the hole of the annular structure in the incident direction of the incident light.

### BRIEF DESCRIPTION OF DRAWINGS

FIG. 1 is a diagram illustrating an example of a stacked structure of a solid-state imaging element of the present disclosure.

FIG. 2 is a diagram illustrating a configuration example of a light-receiving chip in FIG. 1.

FIG. 3 is a diagram illustrating a configuration example of a logic chip in FIG. 1.

FIG. 4 is a diagram illustrating a configuration example of a pixel circuit.

FIG. 5 is a diagram illustrating a configuration example of a pixel circuit in which an anode and a cathode of a photodiode are reversed in the pixel circuit in FIG. 4.

FIG. 6 is a diagram illustrating a basic configuration example of a pixel structure.

FIG. 7 is a diagram illustrating a potential distribution in the pixel structure in FIG. 6.

FIG. 8 is a diagram illustrating an electric field intensity distribution in the pixel structure in FIG. 6.

FIG. 9 is a diagram illustrating a configuration example of a first embodiment of a pixel structure.

FIG. 10 is a diagram illustrating a potential distribution in the pixel structure in FIG. 9.

FIG. 11 is a diagram illustrating an electric field intensity distribution in the pixel structure in FIG. 9.

FIG. 12 is a diagram illustrating a configuration example of a second embodiment of a pixel structure.

FIG. 13 is a diagram illustrating a potential distribution in the pixel structure in FIG. 12.

FIG. 14 is a diagram illustrating an electric field intensity distribution in the pixel structure in FIG. 12.

FIG. 15 is a diagram illustrating a configuration example of a third embodiment of a pixel structure.

FIG. 16 is a diagram illustrating a potential distribution in the pixel structure in FIG. 15.

FIG. 17 is a diagram illustrating an electric field intensity distribution in the pixel structure in FIG. 15.

FIG. 18 is a diagram illustrating a configuration example of a fourth embodiment of a pixel structure.

FIG. 19 is a diagram illustrating a potential distribution in the pixel structure in FIG. 18.

FIG. 20 is a diagram illustrating an electric field intensity distribution in the pixel structure in FIG. 18.

FIG. 21 is a diagram illustrating a configuration example of a fifth embodiment of a pixel structure.

FIG. 22 is a diagram illustrating a potential distribution in the pixel structure in FIG. 20.

FIG. 23 is a diagram illustrating an electric field intensity distribution in the pixel structure in FIG. 20.

FIG. 24 is a diagram illustrating a configuration example of a sixth embodiment of a pixel structure.

FIG. 25 is a diagram illustrating a potential distribution in the pixel structure in FIG. 24.

FIG. 26 is a diagram illustrating an electric field intensity distribution in the pixel structure in FIG. 24.

FIG. 27 is a diagram illustrating a configuration example of a seventh embodiment of a pixel structure.

FIG. 28 is a diagram illustrating a potential distribution in the pixel structure in FIG. 27.

FIG. 29 is a diagram illustrating an electric field intensity distribution in the pixel structure in FIG. 27.

FIG. 30 is a diagram illustrating a configuration of an imaging device and an electronic device using a solid-state imaging element including a semiconductor imaging element to which the present technology is applied.

FIG. 31 is a diagram illustrating a usage example of the solid-state imaging element.

### MODE FOR CARRYING OUT THE INVENTION

A preferred embodiment of the present disclosure is hereinafter described in detail with reference to the accompanying drawings. Note that, in this specification and the drawings, the components having substantially the same functional configuration are assigned with the same reference sign and the description thereof is not repeated.

Hereinafter, a mode for carrying out the present technology is described. The description is given in the following order.
1. First Embodiment
2. Second Embodiment
3. Third Embodiment
4. Fourth Embodiment
5. Fifth Embodiment
6. Sixth Embodiment
7. Seventh Embodiment
8. Application Example to Electronic Device
9. Usage Example of Solid-State Imaging Element

### 1. First Embodiment

### Configuration Example of Solid-State Imaging Element

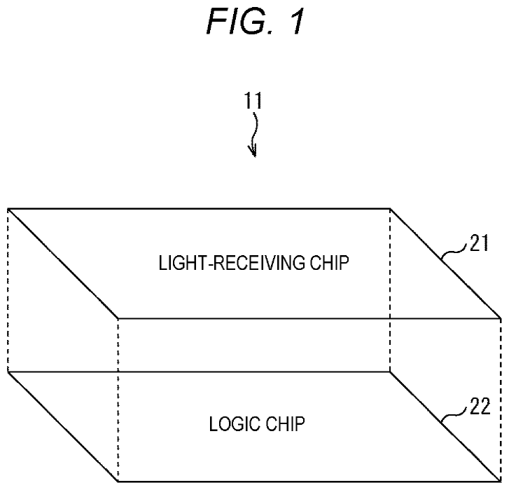

FIG. 1 is a diagram illustrating an example of a stacked structure of a solid-state imaging element 11 in a first embodiment of the present disclosure. This solid-state imaging element 11 is provided with a light-receiving chip 21 and a logic chip 22 stacked on the light-receiving chip 21. A signal line for transmitting a signal is provided between these chips.

### Configuration Example of Light-Receiving Chip

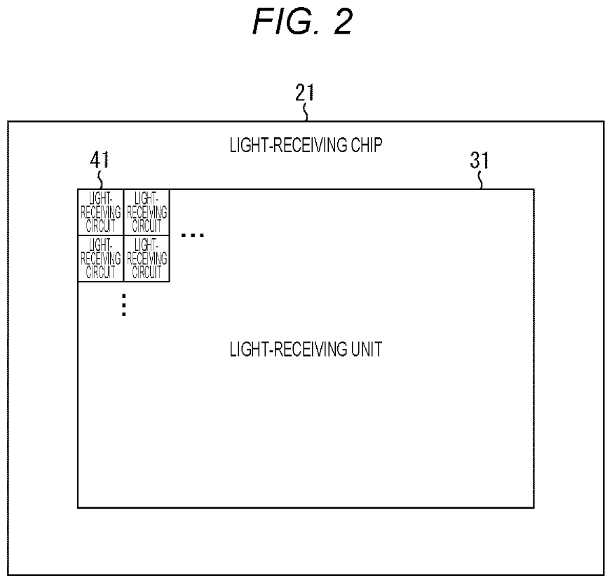

FIG. 2 is a plan view illustrating a configuration example of the light-receiving chip 21 in the first embodiment of the present disclosure. The light-receiving chip 21 is provided with a light-receiving unit 31, and the light-receiving unit 31 is provided with a plurality of light-receiving circuits 41 in a two-dimensional lattice pattern. The light-receiving circuit 220 is described later in detail.

### Configuration Example of Logic Chip

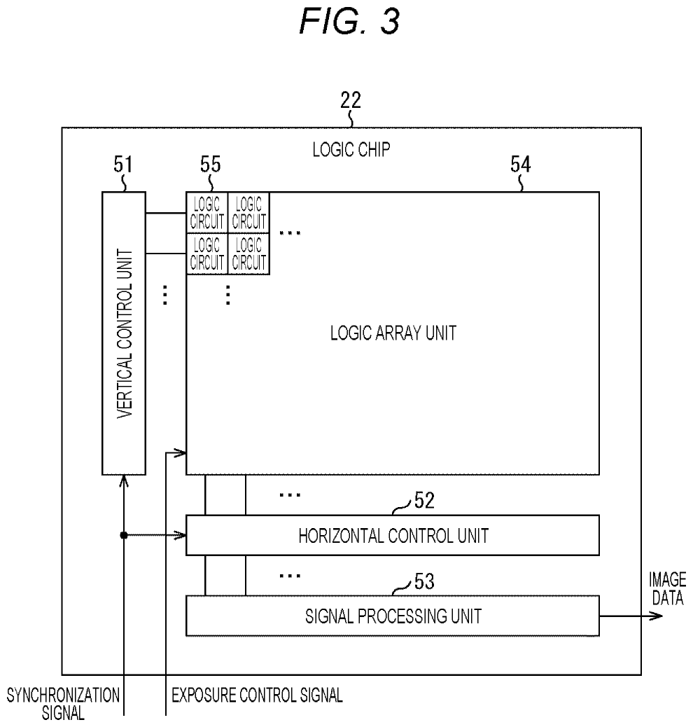

FIG. 3 is a block diagram illustrating a configuration example of the logic chip 22 in the first embodiment of the present disclosure. On the logic chip 22, a vertical control unit 51, a logic array unit 54, a horizontal control unit 52, and a signal processing unit 53 are arranged.

Furthermore, in the logic array unit 54, a logic circuit 55 is arranged for each light-receiving circuit 41. Each of these logic circuits 55 is connected to the corresponding light-receiving circuit 41 via the signal line.

A circuit including the light-receiving circuit 41 and the logic circuit 55 corresponding to the circuit functions as a pixel circuit that generates a pixel signal of one pixel in image data.

Then, a vertical synchronization signal is input to the vertical control unit 51, and a horizontal synchronization signal is input to the horizontal control unit 52. An exposure control signal is input to the logic array unit 54.

Hereinafter, a set of pixel circuits (light-receiving circuits 41 and logic circuits 55) arranged in a predetermined direction (such as a horizontal direction) is referred to as a “row”, and a set of pixel circuits arranged in a direction perpendicular to the row is referred to as a “column”.

The vertical control unit 51 sequentially selects the row in synchronization with the vertical synchronization signal. The logic circuit 55 counts the number of photons in an exposure period and outputs a signal indicating a counted value as the pixel signal.

The horizontal control unit 52 sequentially selects the column in synchronization with the horizontal synchronization signal and outputs the pixel signal.

The signal processing unit 53 executes predetermined signal processing such as filter processing on the image data including the pixel signal. The signal processing unit 53 outputs the processed image data to a recording unit not illustrated.

### Configuration Example of Pixel Circuit

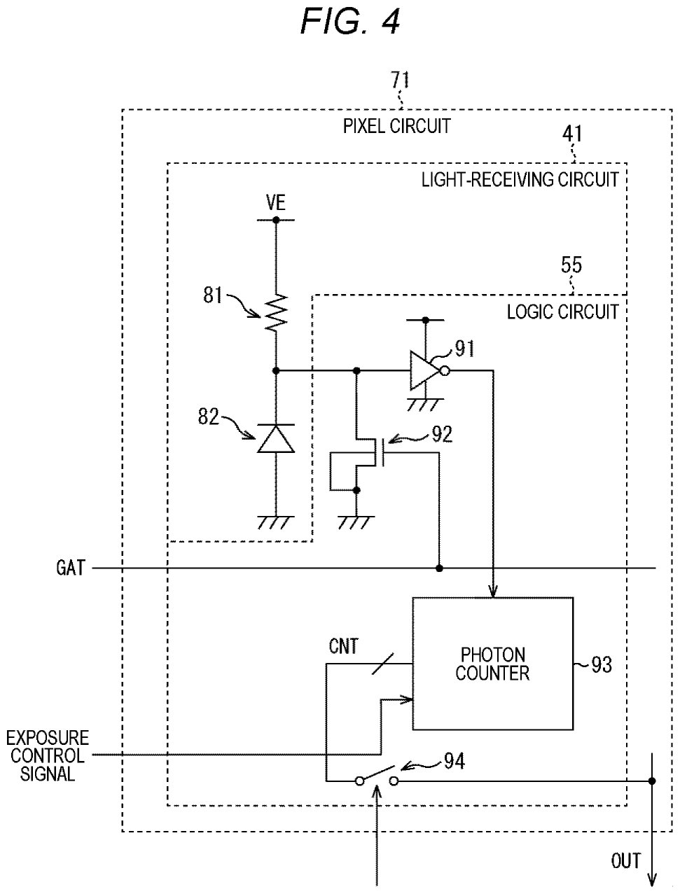

FIG. 4 is a circuit diagram illustrating a configuration example of a pixel circuit 71 in the first embodiment of the present disclosure. The pixel circuit 71 is provided with the light-receiving circuit 41 and the logic circuit 55.

The light-receiving circuit 41 is provided with a resistor 81 and a photodiode 82. Furthermore, the logic circuit 55 is provided with an inverter 91, a transistor 92, a photon counter 93, and a switch 94.

The photodiode 82 photoelectrically converts incident light to output a photocurrent. A cathode of the photodiode 82 is connected to a terminal (such as a ground terminal) having a potential lower than a potential of a power source VE via the resistor 81. Therefore, a reverse bias is applied to the photodiode 82. Furthermore, the photocurrent flows in a direction from the cathode to an anode of the photodiode 82.

As the photodiode 82, for example, an avalanche photodiode that amplifies the photocurrent is used. Furthermore, it is especially desirable to use a single photon avalanche diode (SPAD) among the avalanche diodes. The SPAD is a type of the avalanche photodiode, and has such high sensitivity that one photon may be detected.

One end of the resistor 81 is connected to the power source VE, and the other end thereof is connected to the cathode of the photodiode 82. Every time the photocurrent is output, the photocurrent flows through the resistor 81, and a cathode potential of the photodiode 82 drops to a value lower than the potential of the power source VE.

The inverter 91 inverts a signal of the cathode potential of the photodiode 81 and outputs the same as a pulse signal OUT to the photon counter 93. The inverter 91 outputs a low-level pulse signal OUT in a case where the cathode potential is higher than a predetermined value, and outputs a high-level pulse signal OUT in a case where this is equal to or lower than the predetermined value.

To a gate of the transistor 92, a gate signal GAT from the vertical control unit 51 is applied, a source thereof is connected to a back gate and a ground terminal, and a drain thereof is connected to the cathode of the photodiode 82 and an input terminal of the inverter 91. As the transistor 92, for example, an N type metal oxide semiconductor (MOS) transistor is used. The vertical control unit 51 supplies a low-level gate signal GAT to the selected row, for example.

The photon counter 93 counts the number of times the high-level pulse signal OUT is output in the exposure period. The photon counter 93 sets a count value CNT to an initial value (for example, “0”) when exposure starts, and counts over the exposure period. Then, the photon counter 93 stops counting when the exposure ends, and outputs the count value CNT to the switch 94.

As illuminance of the incident light on the pixel circuit 71 is higher, incidence frequency of the photons in the incident light becomes higher. Then, as the incidence frequency of the photons is higher, frequency of drop of the cathode potential of the photodiode 82 becomes higher, and output frequency of the high-level pulse signal becomes higher. Then, as the output frequency of the pulse signal is higher, the value of the count value CNT when the exposure ends becomes larger. That is, the count value CNT is a value obtained by measuring the illuminance.

The switch 94 outputs a signal of the count value CNT as the pixel signal OUT to the signal processing unit 53 under the control of the horizontal control unit 52.

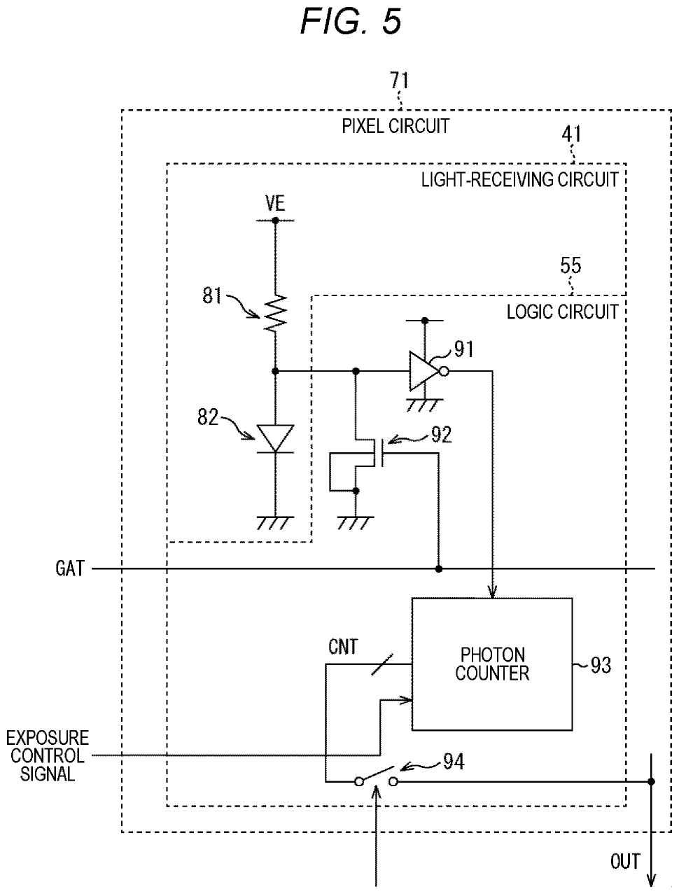

Note that, in the pixel circuit 71 in FIG. 4, the circuit configuration example in which the cathode of the photodiode 82 is connected to the resistor 81 is described; however, as illustrated in the pixel circuit 71 in FIG. 5, the anode of the photodiode 82 may also be connected to the resistor 81.

### Basic Configuration Example of Pixel Structure

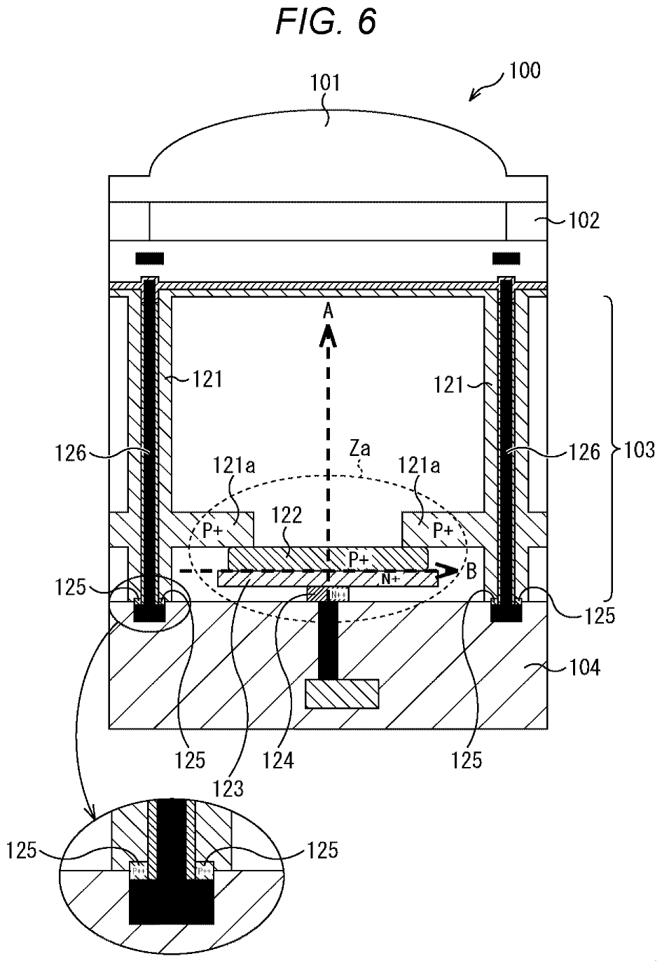

FIG. 6 illustrates a basic structure example of a pixel structure of a pixel 100. Note that, the pixel structure of the pixel 100 illustrated in FIG. 6 illustrates a physical structure in units of one pixel 100 for implementing the pixel circuit 71 functioning as a light-receiving element referred to as an avalanche photodiode (single photon avalanche diode (SPAD)) described above. As illustrated in FIG. 6, the pixel 100 includes an on-chip lens 101, a color filter 102, a photoelectric conversion layer 103, and a substrate 104 from the top in the drawing.

Note that, in FIG. 6, the incident light is incident from an upper part toward a lower part in the drawing.

The on-chip lens 101 is a lens corresponding to a size of the pixel 100, and condenses the incident light in such a manner that the photoelectric conversion layer 103 is a focal position.

The color filter 102 transmits light of a specific wavelength such as RGB out of the incident light to the photoelectric conversion layer 103.

The photoelectric conversion layer 103 is formed on the substrate 104 and generates electrons corresponding to an amount of the incident light transmitted through the on-chip lens 101 and the color filter 102 in units of pixels. As the substrate 104, for example, any of Si, Ge, GeSi, an organic semiconductor and the like may be used.

A disk-shaped cathode 124 including N++ (N++ type semiconductor region) is formed on a surface of the substrate 104 at the center position of the pixel 100. Furthermore, as illustrated in an enlarged view in a lower part in FIG. 6, an anode 125 including P++ (P++ type semiconductor region) is formed on the surface of the substrate 104 at a boundary 126 between the pixels 100. Note that, the anode 125 may be embedded in the substrate 104 at the boundary 126.

Furthermore, a disk-shaped N+ portion 123 including N+ (N+ type semiconductor region) is formed on the cathode 124 in the drawing, and a disk-shaped P+ portion 122 including P+ (P+ type semiconductor region) is further formed thereon.

The N+ portion 123 is formed coaxially with the center position of the pixel 100 into a disk shape having a diameter larger than that of the cathode 124.

The P+ portion 122 is formed immediately above the N+ portion 123 so as to be coaxially with the cathode 124 into a disk shape having a diameter larger than that of the cathode 124 and smaller than that of the N+ portion 123.

A P+ portion 121 including P+ (P+ type semiconductor region) is formed on a pixel center side of the boundary 126 of each pixel 100 and a portion immediately below the on-chip lens 102.

Furthermore, as a part of the P+ portion 121, an annular portion 121a protruding in a direction perpendicular to a surface forming the boundary 126 toward the pixel center, the portion having an annular (donut-shaped) structure with a hole formed at the center as seen in the incident direction of the incident light is formed so as to be in contact with an outer edge of the disk-shaped P+ portion 122.

An avalanche photodiode (single photon avalanche diode (SPAD)) is formed by the pixel structure including the P+ portion 121, the annular portion 121a, the P+ portion 122, the N+ portion 123, the cathode 124, and the anode 125 forming the pixel 100. In the avalanche photodiode, when a voltage is applied between the anode 125 and the cathode 124, an electric field having a predetermined intensity is generated in the annular portion 121a, the P+ portion 122, and the N+ portion 123 in the vicinity of the center of the pixel 100, so that an avalanche region Za is formed.

The electrons generated by the photoelectric conversion are multiplied by an avalanche breakdown phenomenon occurring when the voltage is applied between the anode 125 and the cathode 124 forming the avalanche region Za, thereby implementing highly sensitive light reception also for weak incident light.

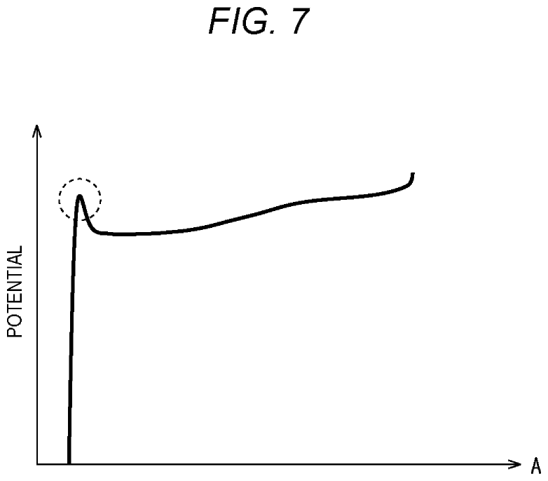

More specifically, a potential distribution in an up-and-down direction in the drawing at the pixel center indicated by an arrow A direction in FIG. 6 is formed as illustrated in FIG. 7, so that a distribution in which the potential decreases toward the cathode 124 is formed.

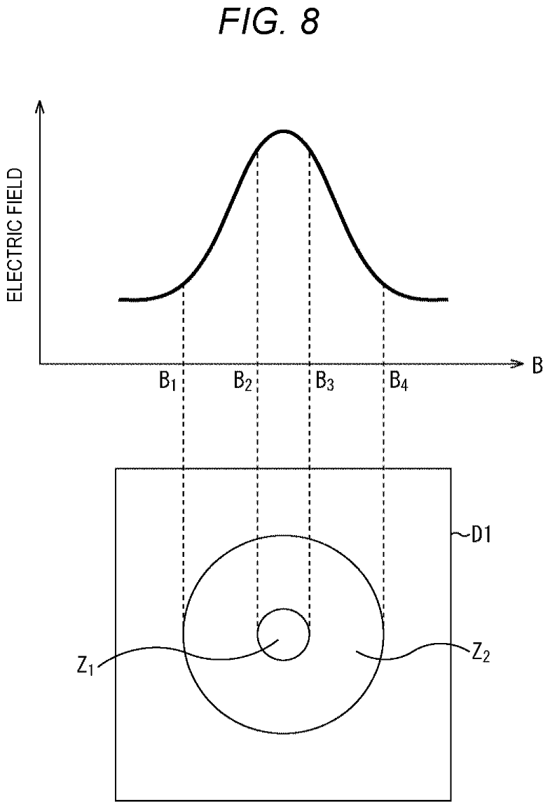

At that time, a predetermined voltage is applied between the anode 125 and the cathode 124, so that an electric field intensity distribution as illustrated in FIG. 8 is formed in an arrow B direction in FIG. 6.

The electric field intensity distribution in FIG. 8 is made the distribution in which the electric field intensity reaches its peaks in the vicinity of the center of the pixel 100 in the arrow B direction, and for example, an electric field of 0.4 to 0.6 MV/cm in which the avalanche breakdown occurs is formed in a range between positions B1 and B2 in the vicinity of the center. That is, in the pixel 100 having a side sectional structure in FIG. 6, the electric field distribution having the highest intensity at the center is formed.

Note that, an upper part in FIG. 8 is a graph illustrating the electric field intensity distribution in the horizontal direction in the arrow B direction, and a lower part in FIG. 8 is an electric field intensity distribution D1 on a two-dimensional plane when the pixel 100 is seen from above.

As indicated by the electric field intensity distribution D1 in the lower part in FIG. 8, a range Z2 corresponding to the positions B1 to B4 in the upper part in FIG. 8 is made an electric field intensity range of 0.4 to 0.6 MV/cm in which the avalanche breakdown occurs. Furthermore, a range Z1 corresponding to the positions B2 to B3 in the upper part in FIG. 8 is the range in which the electric field intensity is especially high.

Note that, a density of each of the P+ portion 121, the P+ portion 122, the N+ portion 123, the cathode 124, and the anode 125, and a potential difference between the cathode 124 and the anode 125 are set in such a manner that the electric field intensity becomes the electric field intensity of 0.4 to 0.6 MV/cm that causes the avalanche breakdown in the avalanche region Za, especially in the vicinity of the center position of the pixel 100 in the arrow B direction.

In a case in FIG. 6, for example, the density of the P+ portion 121, the P+ portion 122, and the N+ portion 123 is set to about 1e16 to 5e17 (1/cm³), the density of the cathode 124 and the anode 125 is set to about 1e20 (1/cm³), and the voltage applied between the cathode 124 and the anode 125 is set to about 15 V to 30 V, so that the electric field intensity in the avalanche region Za may be set to 0.4 to 0.6 MV/cm.

That is, in the pixel structure of the pixel 100 in FIG. 6, the potential distribution as illustrated in FIG. 7 and the electric field intensity distribution as illustrated in FIG. 8 are formed, so that the electrons generated in the photoelectric conversion layer 103 are transferred to the center of the pixel 100 in the incident direction of the incident light, thereby advancing toward the cathode 124, and when they pass through the avalanche region Za formed in the vicinity of a boundary between the P+ portion 122 and the N+ portion 123, the avalanche breakdown occurs and multiplication of the electrons occurs.

Therefore, in the pixel 100 having a side structure in FIG. 6, even with the incident light of a slight light amount, the light-receiving sensitivity may be enhanced by multiplication of the electrons by the avalanche breakdown.

However, in the side structure of the pixel 100 in FIG. 6, since the P+ portion 122 is formed, a potential barrier as indicated by a convex potential distribution surrounded by a dotted line in FIG. 7 is formed, and transfer of the electrons is inhibited.

As a result, in the pixel 100 having the side sectional structure in FIG. 6, there is a possibility that the transfer of the electrons is inhibited, so that the light-receiving sensitivity is deteriorated.

Therefore, in the present disclosure, a component corresponding to the P+ portion 122 is omitted, so that the generation of the potential barrier is suppressed and the light-receiving sensitivity is improved.

<Pixel Structure of Present Disclosure>

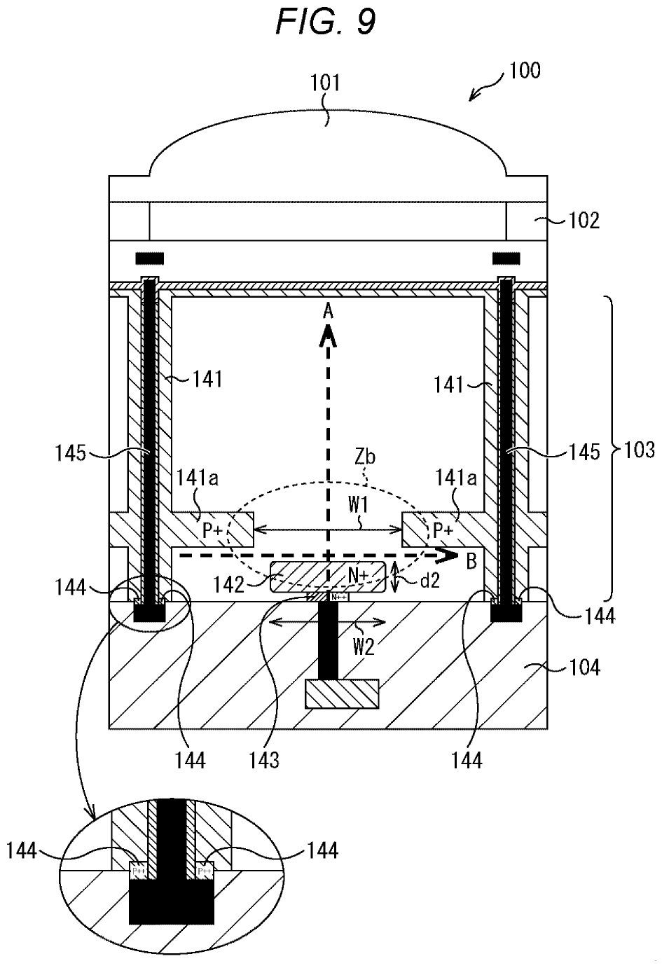

FIG. 9 is a side sectional view illustrating a pixel structure of the present disclosure.

Note that, in the pixel structure in FIG. 9, components having the same functions as those of the pixel structure in FIG. 6 are denoted by the same reference signs, and the description thereof is omitted as appropriate.

In a pixel 100 in FIG. 9, a structure of a photoelectric conversion layer 103 is different from that in FIG. 6.

The photoelectric conversion layer 103 in FIG. 9 includes a P+ portion 141, an N+ portion 142, a cathode 143, an anode 144, and a boundary 145.

Note that, the P+ portion 141, the N+ portion 142, the cathode 143, the anode 144, and the boundary 145 are components corresponding to the P+ portion 121, the N+ portion 122, the cathode 124, the anode 125, and the boundary 126 in FIG. 6, respectively.

That is, a disk-shaped cathode 143 including N++(N++ type semiconductor region) is formed on a surface of a substrate 104 at the center position of the pixel 100. Furthermore, as illustrated in an enlarged view in a lower part in FIG. 9, the anode 144 including P++ (P++ type semiconductor region) is formed in the vicinity of the surface of the substrate 104 at the boundary 145 between the pixels 100.

Furthermore, a disk-shaped N+ portion 142 including N+ (N+ type semiconductor region) is formed on the cathode 143 in the drawing.

The N+ portion 142 is formed coaxially with the center position of the pixel 100 into a disk shape having a diameter larger than that of the cathode 143.

The P+ portion 141 including P+(P+ type semiconductor region) is formed on a pixel center side of the boundary 145 of each pixel 100 and a portion immediately below the on-chip lens 102.

Furthermore, as a part of the P+ portion 141, an annular portion 141a protruding in a direction perpendicular to a surface forming the boundary 145 toward the pixel center, the portion having an annular (donut-shaped) structure as seen in the incident direction of the incident light is formed.

That is, in the pixel structure of the pixel 100 in FIG. 9, a component corresponding to the N+ portion 123 is omitted from the pixel structure in FIG. 6, a diameter W2 of the N+ portion 142 is made smaller than a diameter W1 of a hole of the annular portion 141a, and a thickness d2 of the N+ portion 142 is made larger than a thickness of N+ 122 in FIG. 6.

An avalanche photodiode is formed by a pixel structure including the P+ portion 141, the annular portion 141a, the N+ portion 142, the cathode 143, and the anode 144 forming the pixel 100. In the avalanche photodiode, when a voltage is applied between the anode 144 and the cathode 143, a fringe field is generated by the annular portion 141a and the N+ portion 142 in the vicinity of the center of the pixel 100, so that an avalanche region Zb is formed.

Electrons generated by photoelectric conversion are multiplied by an avalanche breakdown phenomenon occurring in the avalanche region Zb generated when the voltage is applied between the anode 144 and the cathode 143, thereby implementing highly sensitive light reception also for weak incident light.

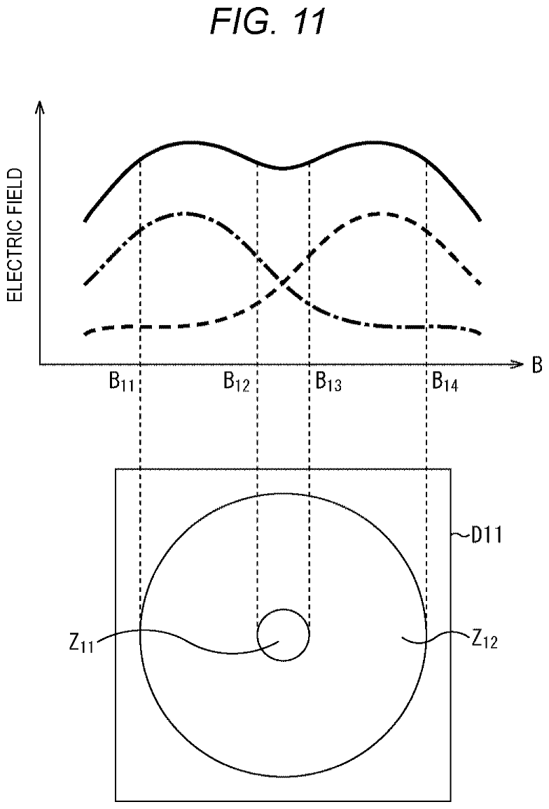

Moreover, in the pixel structure in FIG. 9, an electric field intensity distribution as illustrated in FIG. 11 is formed in an arrow B direction.

That is, the electric field intensity distribution as indicated by a dashed-dotted line in an upper part in FIG. 11 is formed between a left side portion in FIG. 9 in the annular portion 141a and the N+ portion 142, and the electric field intensity distribution as indicated by a dotted line in the upper part in FIG. 11 is formed between a right side portion in FIG. 9 in the annular portion 141a and the N+ portion 142.

As a result, by the fringe field formed between the annular portion 141a and the N+ portion 142, the electric field intensity distribution formed into an annular shape including the electric field intensity distribution indicated by the dashed-dotted line and the electric field intensity distribution indicated by the dotted line in FIG. 11 is synthesized, thereby forming the electric field intensity distribution having two peaks as indicated by a solid line in the upper part in FIG. 11.

That is, in the pixel structure of the pixel 100 in FIG. 9, as indicated by an electric field intensity distribution D11 when seen from an upper surface of the pixel 100 (when seen in the incident direction of the incident light) in a lower part in FIG. 11, in a range Z12 corresponding to positions B11 to B14 in the upper part in FIG. 11, the electric field intensity is set to 0.4 to 0.6 MV/cm or higher with which the avalanche breakdown occurs, and in a range Z11 in the vicinity of the center of the electric field intensity distribution D11 corresponding to the vicinity of the center of the pixel 100, the electric field intensity is set lower than that in the range Z12, but is set to 0.4 MV/cm or higher with which the avalanche breakdown occurs.

That is, in the electric field intensity distribution in the pixel structure in FIG. 9, as compared with the vicinity of the center of the pixel 100, a range in a peripheral portion thereof is formed as the range in which the electric field intensity is higher; however, the electric field intensity is 0.4 MV/cm or higher also in the range Z11 in the vicinity of the center, and the avalanche breakdown may be caused.

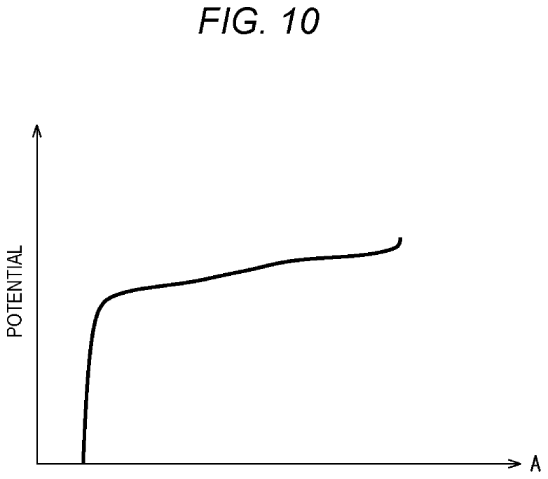

As a result, in the pixel 100 having the pixel structure in FIG. 9, the generation of the potential barrier is suppressed on the basis of the potential distribution as illustrated in FIG. 10 and the electric field intensity distribution as illustrated in FIG. 11, so that light-receiving sensitivity in a fine pixel 100 may be improved.

Note that, in a case in FIG. 9, for example, the density of the P+ portion 141 and the N+ portion 142 is set to about 1e16 to 5e17 (1/cm³), the density of the cathode 143 and the anode 144 is set to about 1e20 (1/cm³), and the voltage applied between the cathode 143 and the anode 144 is adjusted, so that the electric field intensity in the avalanche region Zb may be set to 0.4 to MV/cm.

Furthermore, the density of each of the P+ portion 141, the N+ portion 142, the cathode 143, and the anode 144, and a potential difference between the cathode 143 and the anode 144 are merely examples, and are not limited thereto.

Note that, as for the P type, the N type, the electron, the hole and the like, the polarity may be opposite, and it is similar also in the following embodiments.

### 2. Second Embodiment

Although the example in which the component corresponding to the P+ portion 122 forming the basic pixel structure in FIG. 6 is omitted is described above, a component corresponding to the N+ portion 123 in FIG. 6 may be omitted as long as the avalanche region may be formed.

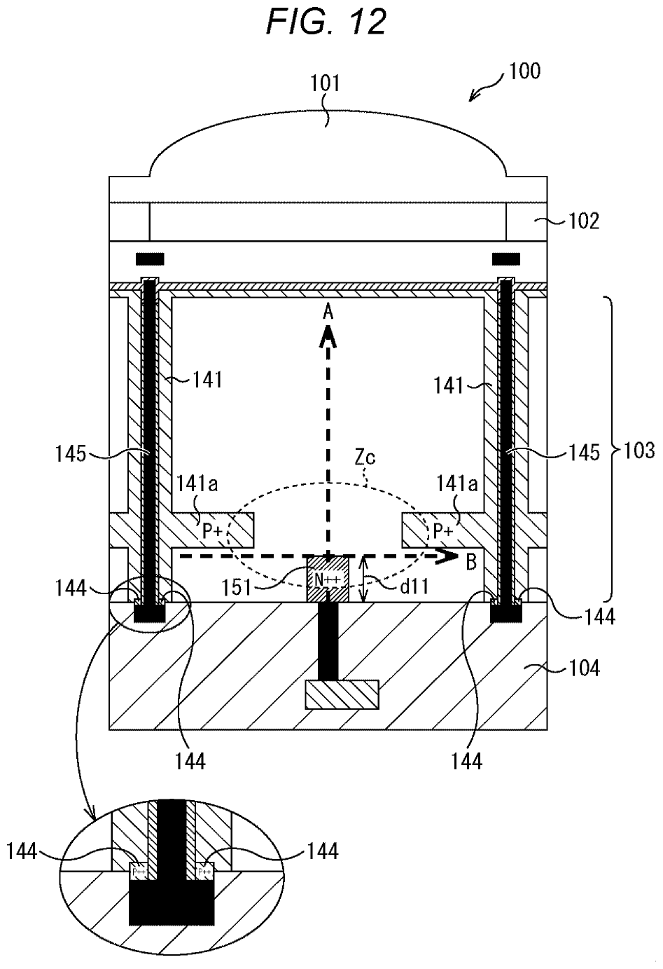

FIG. 12 illustrates a pixel structure of a pixel 100 in which a configuration of an N+ portion 142 corresponding to a configuration of the N+ portion 123 in FIG. 6 in the pixel structure in FIG. 9 is omitted.

Note that, in the pixel structure in FIG. 12, components having the same functions as those of the pixel structure in FIG. 9 are denoted by the same reference signs, and the description thereof is omitted as appropriate.

The pixel structure in FIG. 12 is different from the pixel structure in FIG. 9 in providing a cathode 151 in place of the N+ portion 142 and the cathode 143.

That is, in the pixel structure in FIG. 12, the N+ portion 142 is omitted, and the cathode 151 has a thickness d11 larger than that of the cathode 143.

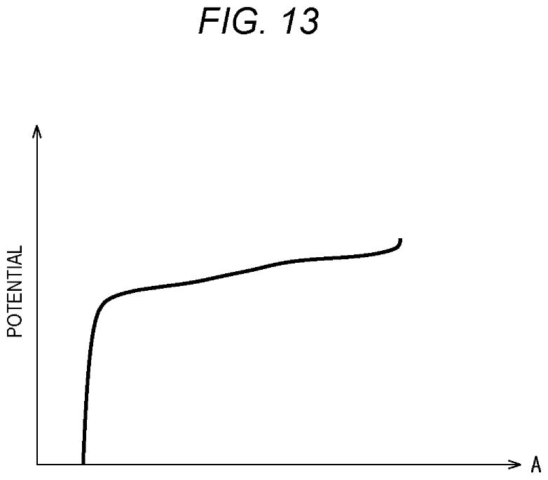

With such a structure, a potential distribution in an arrow A direction in the pixel structure in FIG. 12 is made the distribution that monotonously changes with respect to a change in position in the arrow A direction as illustrated in FIG. 13, so that the potential barrier surrounded by the dotted line in FIG. 7 is not generated.

Furthermore, in the pixel structure in FIG. 12, an avalanche region Zc is formed by a fringe field generated between an annular portion 141a in a P+ portion 141 and a disk-shaped cathode 151, and avalanche breakdown occurs.

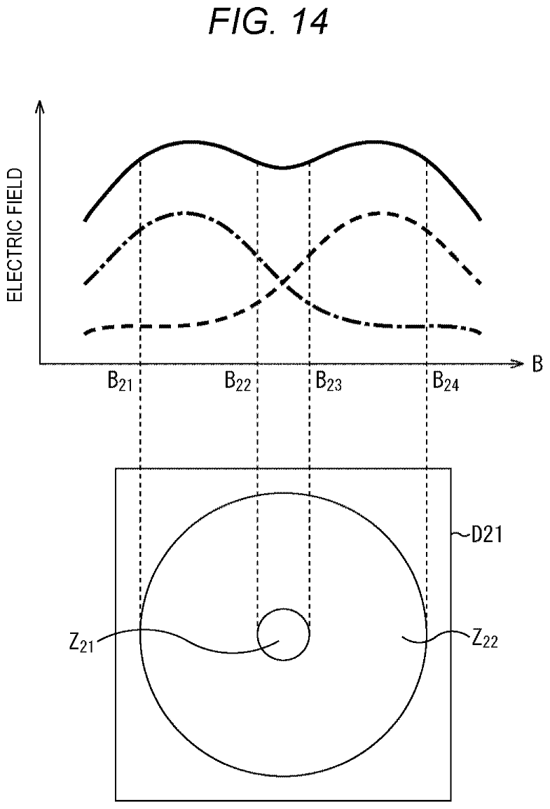

Moreover, in the pixel structure in FIG. 12, an electric field intensity distribution as illustrated in FIG. 14 is formed in an arrow B direction.

That is, the electric field intensity distribution as indicated by a dashed-dotted line in an upper part in FIG. 14 is formed between a left side portion in FIG. 12 in the annular portion 141a and the cathode 151, and the electric field intensity distribution as indicated by a dotted line in the upper part in FIG. 14 is formed between a right side portion in FIG. 12 in the annular portion 141a and the cathode 151.

As a result, by the fringe field formed between the annular portion 141a and the cathode 151, the electric field intensity distribution including the electric field intensity distribution indicated by the dashed-dotted line and the electric field intensity distribution indicated by the dotted line in FIG. 14 is synthesized, thereby forming the electric field intensity distribution having two peaks as indicated by a solid line in the upper part in FIG. 14.

At that time, in the pixel structure in FIG. 12, as indicated by an electric field intensity distribution D21 when seen from an upper surface of the pixel 100 (when seen in an incident direction of incident light), in a range Z22 corresponding to positions B21 to B24 in the upper part in FIG. 14, the electric field intensity is set to 0.4 to 0.6 MV/cm or higher with which the avalanche breakdown occurs, and in a range Z21 in the vicinity of the center of the electric field intensity distribution D21 corresponding to the vicinity of the center of the pixel 100, the electric field intensity is set lower than that in the range Z22, but is set to 0.4 MV/cm or higher with which the avalanche breakdown occurs.

That is, in the pixel structure in FIG. 12, as compared with the vicinity of the center of the pixel 100, a range in a peripheral portion thereof is formed as the range in which the electric field intensity is higher; however, the electric field intensity is 0.4 MV/cm or higher also in the range Z21 in the vicinity of the center, and the avalanche breakdown may be caused.

As a result, in the pixel 100 having the pixel structure in FIG. 12, the generation of the potential barrier is suppressed on the basis of the potential distribution as illustrated in FIG. 13 and the electric field intensity distribution as illustrated in FIG. 14, so that light-receiving sensitivity in a fine pixel 100 may be improved.

Note that, in a case in FIG. 12, for example, the density of the P+ portion 141 is set to about 1e16 to 5e17 (1/cm³), the density of the cathode 151 and the anode 144 is set to about 1e20 (1/cm³), and the voltage applied between the cathode 151 and the anode 144 is adjusted, so that the electric field intensity in the avalanche region Zc may be set to 0.4 to 0.6 MV/cm.

Furthermore, the density of each of the P+ portion 141, the cathode 151, and the anode 144, and a potential difference between the cathode 151 and the anode 144 are merely examples, and are not limited thereto.

### 3. Third Embodiment

Although the example in which the components corresponding to the P+ portion 122 and the N+ portion 123 forming the basic pixel structure in FIG. 6 is omitted is described above, an N+ portion may be formed to surround the cathode 151 in FIG. 12.

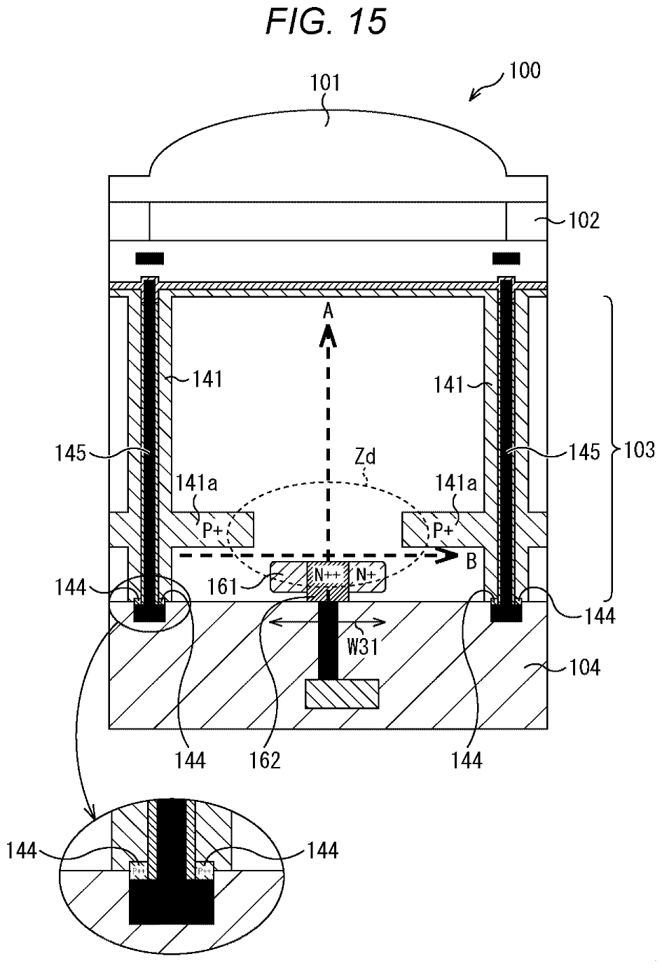

FIG. 15 illustrates a pixel structure of a pixel 100 in which a component corresponding to the N+ portion 142 in FIG. 9 is formed so as to surround the cathode 151 in the pixel structure in FIG. 12.

Note that, in the pixel structure in FIG. 15, components having the same functions as those of the pixel structure in FIG. 12 are denoted by the same reference signs, and the description thereof is omitted as appropriate.

The pixel structure in FIG. 15 is different from the pixel structure in FIG. 12 in providing an N+ portion 161 and a cathode 162 in place of the cathode 151.

That is, in the pixel structure in FIG. 15, the cathode 162 corresponding to the cathode 151 is provided, and the N+ portion 161 having an annular structure is formed around the same. A diameter W31 of the N+ portion 161 is, for example, the same as the diameter W2 of the N+ portion 142 in FIG. 9.

Furthermore, in the pixel structure in FIG. 15, an avalanche region Zd is formed by a fringe field generated between an annular portion 141a in a P+ portion 141 and the N+ portion 161 having the annular structure, and avalanche breakdown occurs.

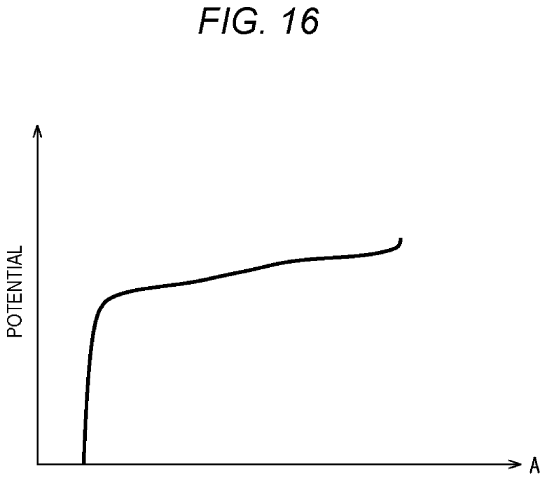

With such a structure, a potential distribution in an arrow A direction in the pixel structure in FIG. 15 is made the distribution that monotonously changes with respect to a change in position in the arrow A direction as illustrated in FIG. 16, so that the potential barrier surrounded by the dotted line in FIG. 7 is not generated.

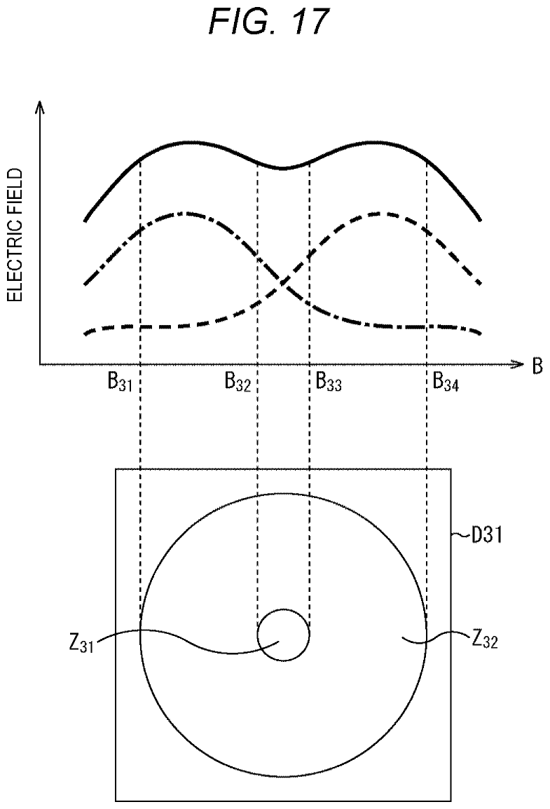

Moreover, in the pixel structure in FIG. 15, an electric field intensity distribution as illustrated in FIG. 17 is formed in an arrow B direction.

That is, the electric field intensity distribution as indicated by a dashed-dotted line in an upper part in FIG. 17 is formed between a left side portion in FIG. 15 in the annular portion 141a and the N+ portion 161, and the electric field intensity distribution as indicated by a dotted line in the upper part in FIG. 17 is formed between a right side portion in FIG. 15 in the annular portion 141a and the N+ portion 161.

As a result, by the fringe field formed between the annular portion 141a and the N+ portion 161, the electric field intensity distribution including the electric field intensity distribution indicated by the dashed-dotted line and the electric field intensity distribution indicated by the dotted line in FIG. 17 is synthesized, thereby forming the electric field intensity distribution having two peaks as indicated by a solid line in the upper part in FIG. 17.

At that time, in the pixel structure in FIG. 15, as indicated by an electric field intensity distribution D31 when seen from an upper surface of the pixel 100 (when seen in an incident direction of incident light), in a range Z32 corresponding to positions B31 to B34 in the upper part in FIG. 15, the electric field intensity is set to 0.4 to 0.6 MV/cm or higher with which the avalanche breakdown occurs, and in a range Z31 in the vicinity of the center of the electric field intensity distribution D31 corresponding to the vicinity of the center of the pixel 100, the electric field intensity is set lower than that in the range Z32, but is set to 0.4 MV/cm or higher with which the avalanche breakdown occurs.

That is, in the pixel structure in FIG. 15, as compared with the vicinity of the center of the pixel 100, a range in a peripheral portion thereof is formed as the range in which the electric field intensity is higher; however, the electric field intensity is 0.4 MV/cm or higher also in the range Z31 in the vicinity of the center, and the avalanche breakdown may be caused.

As a result, in the pixel 100 having the pixel structure in FIG. 15, the generation of the potential barrier is suppressed on the basis of the potential distribution as illustrated in FIG. 16 and the electric field intensity distribution as illustrated in FIG. 17, so that light-receiving sensitivity in a fine pixel 100 may be improved.

Note that, in a case in FIG. 15, for example, the density of the P+ portion 141 and the N+ portion 161 is set to about 1e16 to 5e17 (1/cm³), the density of the anode 144 and the cathode 162 is set to about 1e20 (1/cm³), and the voltage applied between the cathode 162 and the anode 144 is adjusted, so that the electric field intensity in the avalanche region Zb may be set to 0.4 to 0.6 MV/cm.

Furthermore, the density of each of the P+ portion 141, the N+ portion 161, the cathode 162, and the anode 144, and a potential difference between the cathode 162 and the anode 144 are merely examples, and are not limited thereto.

### 4. Fourth Embodiment

Although the example in which the two peaks appear in the electric field intensity distribution is described above; however, it is also possible that a peak appears in the electric field intensity distribution only at the center portion of a pixel 100 by adjusting a relationship between a diameter of a hole of an annular portion 141a and a diameter of an N+ portion 142.

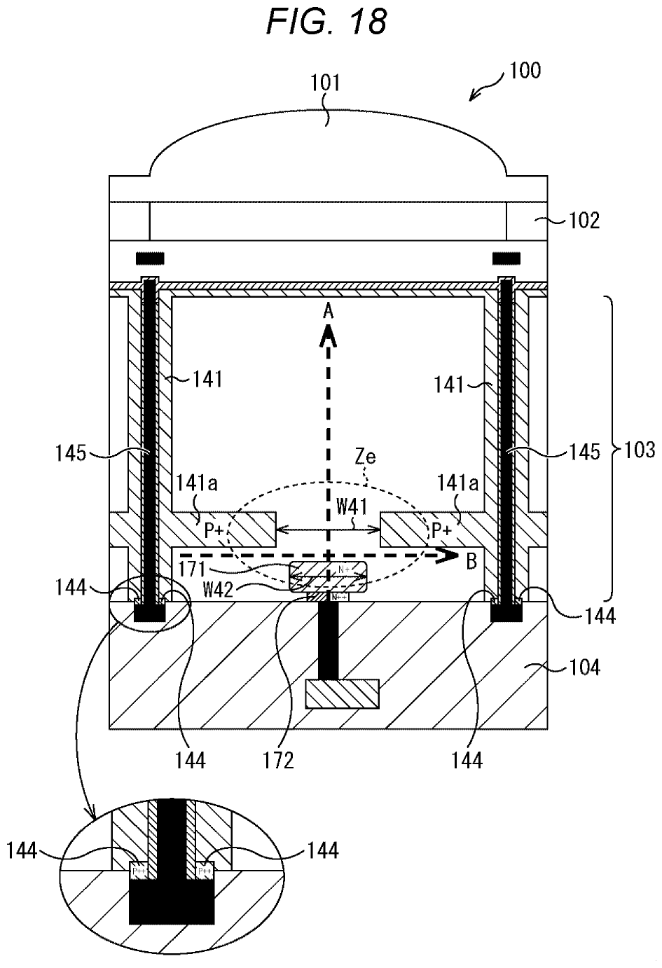

FIG. 18 illustrates an example of a pixel structure of the pixel 100 in which the relationship between the diameter in a horizontal direction of the N+ portion 142 and the diameter of the hole of the annular portion 141a in the pixel structure in FIG. 9 is adjusted, so that the peak of the electric field intensity distribution appears only at the center portion of the pixel 100.

Note that, in the pixel structure in FIG. 18, components having the same functions as those of the pixel structure in FIG. 9 are denoted by the same reference signs, and the description thereof is omitted as appropriate.

The pixel structure in FIG. 18 is different from the pixel structure in FIG. 9 in providing an N+ portion 171 and a cathode 172 in place of the N+ portion 142 and the cathode 143.

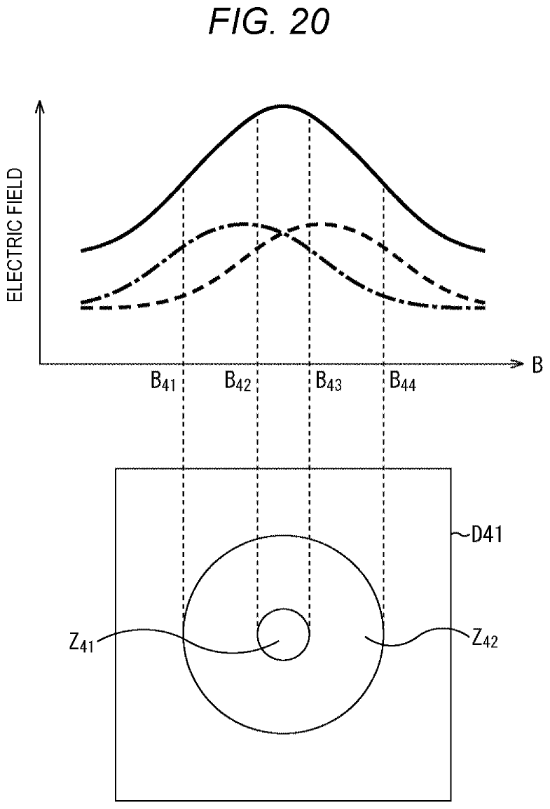

That is, in the pixel structure in FIG. 18, a diameter W41 of the hole in the annular portion 141a and a diameter W42 of the N+ portion 171 are adjusted, and a fringe field formed by the annular portion 141a and the N+ portion 171 is adjusted, so that an electric field intensity distribution (FIG. 20) to be formed is adjusted, and the peak appears only at one location in the vicinity of the center position of the pixel 100.

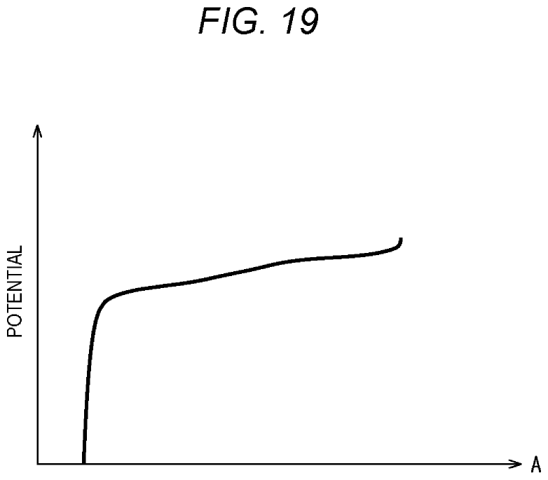

With such a structure also, a potential distribution in an arrow A direction in the pixel structure in FIG. 18 is made the distribution that monotonously changes with respect to a change in position in the arrow A direction as illustrated in FIG. 19, so that the potential barrier surrounded by the dotted line in FIG. 7 is not generated.

Furthermore, in the pixel structure in FIG. 18, an avalanche region Ze is formed by a fringe field generated between the annular portion 141a in a P+ portion 141 and the N+ portion 171, and avalanche breakdown occurs.

Moreover, in the pixel structure in FIG. 18, an electric field intensity distribution as illustrated in FIG. 20 is formed in an arrow B direction.

That is, the electric field intensity distribution as indicated by a dashed-dotted line in an upper part in FIG. 18 is formed between a left side portion in FIG. 18 in the annular portion 141a and the N+ portion 171, and the electric field intensity distribution as indicated by a dotted line in the upper part in FIG. 20 is formed between a right side portion in FIG. 18 in the annular portion 141a and the N+ portion 171.

As a result, by the fringe field formed between the annular portion 141a and the N+ portion 171, the electric field intensity distribution including the electric field intensity distribution indicated by the dashed-dotted line and the electric field intensity distribution indicated by the dotted line in FIG. 20 is synthesized, thereby forming the electric field intensity distribution in which the peak as indicated by a solid line appears only at the center position of the pixel 100 in the upper part in FIG. 20 is formed.

At that time, in the pixel structure in FIG. 18, as indicated by an electric field intensity distribution D41 when seen from an upper surface of the pixel 100, in a range Z42 corresponding to positions B41 to B44 in the upper part in FIG. 20, the electric field intensity is set to 0.4 to 0.6 MV/cm or higher at which avalanche breakdown occurs, and a range Z41 in the vicinity of the center corresponding to positions B42 to B43 in the upper part in FIG. 20 is a range in which the electric field intensity is especially high.

That is, in the pixel structure in FIG. 18, it is possible to form the range in which the electric field intensity is the highest in the vicinity of the center of the pixel 100 and cause the avalanche breakdown.

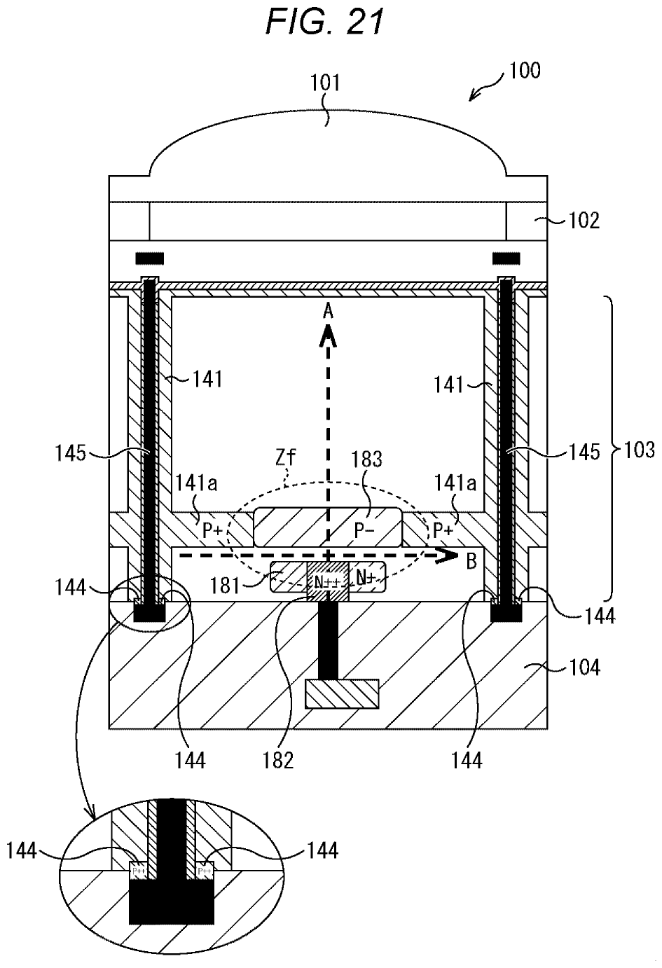

As a result, in the pixel 100 having the pixel structure in FIG. 18, the generation of the potential barrier is suppressed on the basis of the potential distribution as illustrated in FIG. 19 and the electric field intensity distribution as illustrated in FIG. 21, so that light-receiving sensitivity in a fine pixel 100 may be improved.

Note that, in a case in FIG. 18, for example, the density of the P+ portion 141 and the N+ portion 171 is set to about 1e16 to 5e17 (1/cm³), the density of the anode 144 and the cathode 172 is set to about 1e20 (1/cm³), the diameter W41 of the hole of the annular portion 141a is set to 0.5 to 1.5 um, the diameter W42 of the N+ portion 171 is set to W41−0.5 um to W41−0.1 um, and a voltage applied between the N+ portion 171 and the anode 144 is adjusted, so that the electric field intensity in the avalanche region Ze may be set to 0.4 to 0.6 MV/cm.

Furthermore, the density of each of the P+ portion 141, the N+ portion 171, the cathode 172, and the anode 144, the diameter W41 of the hoe of the annular portion 141a, the diameter W42 of the N+ portion 171, and a potential difference between the cathode 162 and the anode 144 are merely examples, and are not limited thereto.

Moreover, although the example of adjusting the diameter W41 of the hole of the annular portion 141a and the diameter W42 of the N+ portion 171 is described above; however, a diameter W31 of the N+ portion 161 in FIG. 15 may be adjusted in place of the N+ portion 171.

### 5. Fifth Embodiment

Although the example in which the peak of the electric field intensity distribution appears only at the center portion of the pixel 100 by adjusting the relationship between the diameter of the hole of the annular portion 141a and the diameter of the N+ portion 142 is described above; however, it is also possible that a P− portion is formed in the hole of the annular portion 141a.

FIG. 21 illustrates an example of a pixel structure of a pixel 100 in which a P− portion is formed in the hole of the annular portion 141a in the pixel structure in FIG. 15.

Note that, in the pixel structure in FIG. 21, components having the same functions as those of the pixel structure in FIG. 15 are denoted by the same reference signs, and the description thereof is omitted as appropriate.

The pixel structure in FIG. 21 is different from the pixel structure in FIG. 15 in providing an N+ portion 181 and a cathode 182 in place of the N+ portion 161 and the cathode 162, and further providing a P− portion 183 in the hole of the annular portion 141a.

That is, the pixel structure in FIG. 21 is different from the pixel structure in FIG. 15 in further providing the P− portion 183 including P− (P− type semiconductor region) in the hole of the annular portion 141a. Note that, the N+ portion 181 and the cathode 182 have the same configurations corresponding to the N+ portion 161 and the cathode 162, respectively.

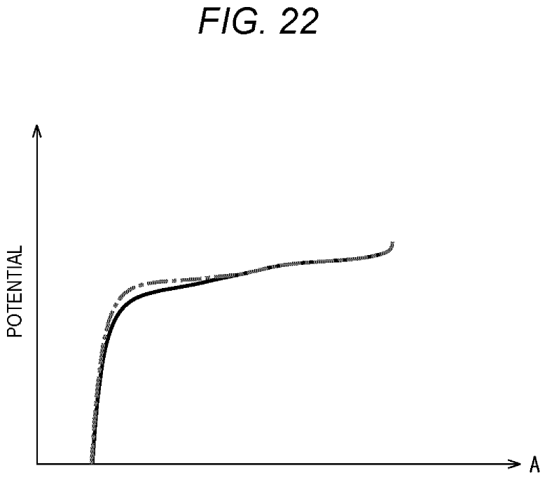

With such a structure, a potential distribution in an arrow A direction in the pixel structure in FIG. 21 is made a distribution as indicated by a solid line against the potential distribution in FIG. 16 indicated by a dashed-dotted line with respect to a change in position in the arrow A direction as illustrated in FIG. 22, so that the potential barrier surrounded by the dotted line in FIG. 7 is not generated, and the potential distribution changes more smoothly than the potential distribution in FIG. 16.

Furthermore, in the pixel structure in FIG. 21, an avalanche region Zf is formed by an effect of an electric field generated between the P− portion and the N+ portion 171 (hereinafter, also referred to as a P− portion electric field) in addition to a fringe field generated between the annular portion 141a in the P+ portion 141 and the N+ portion 181, so that avalanche breakdown occurs.

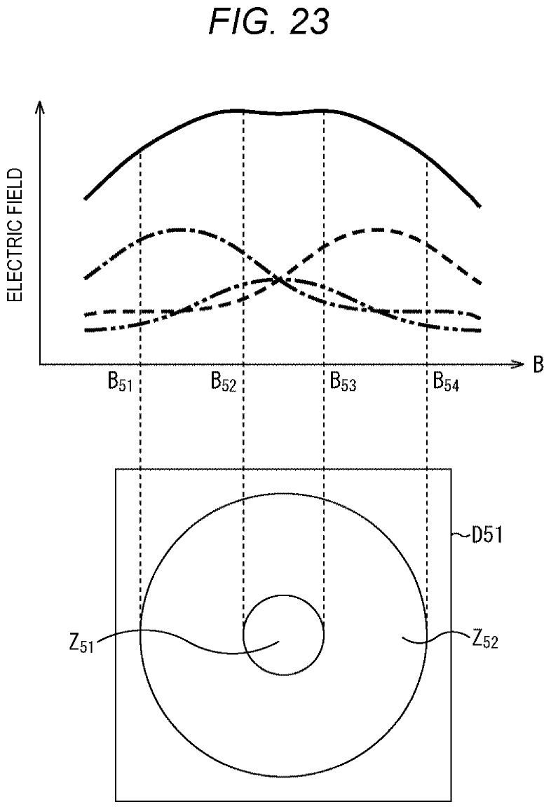

Moreover, in the pixel structure in FIG. 21, an electric field intensity distribution as illustrated in FIG. 23 is formed in an arrow B direction.

That is, the electric field intensity distribution as indicated by a dashed-dotted line in an upper part in FIG. 23 is formed between a left side portion in FIG. 21 in the annular portion 141a and the N+ portion 181, and the electric field intensity distribution as indicated by a dotted line in the upper part in FIG. 23 is formed between a right side portion in FIG. 21 in the annular portion 141a and the N+ portion 171.

Moreover, a P− portion electric field formed between the P− portion 183 and the N+ portion 181 forms an electric field intensity distribution as indicated by a dashed two-dotted line.

As a result, the electric field intensity distribution formed between the annular portion 141a and the N+ portion 181 and the electric field intensity distribution formed between the P− portion 183 and the N+ portion 181 including the electric field intensity distribution indicated by the dashed-dotted line, the electric field intensity distribution indicated by the dotted line, and the electric field intensity distribution indicated by the dashed-two dotted line in FIG. 23 are synthesized by the fringe field formed between the annular portion 141a and the N+ portion 181 and the P− portion electric field formed between the P− portion 183 and the N+ portion 181, so that the electric field intensity distribution in which a wider peak appears at the center position of the pixel 100 as indicated by a solid line in the upper part in FIG. 23 is formed.

At that time, in the pixel structure in FIG. 21, as indicated by an electric field intensity distribution D51 when seen from an upper surface of the pixel 100, in a range Z52 corresponding to positions B51 to B54 in the upper part in FIG. 23, the electric field intensity is set to 0.4 to 0.6 MV/cm or higher with which avalanche breakdown occurs, and there is a wide peak in a range Z51.

That is, in the pixel structure in FIG. 21, it is possible to form the range in which the electric field intensity is the highest in the vicinity of the center of the pixel 100 and cause the avalanche breakdown.

As a result, in the pixel 100 having the pixel structure in FIG. 21, the generation of the potential barrier is suppressed on the basis of the potential distribution as illustrated in FIG. 22 and the electric field intensity distribution as illustrated in FIG. 23, so that light-receiving sensitivity in a fine pixel 100 may be improved.

Note that, in a case in FIG. 21, for example, the density of the P+ portion 141 and the N+ portion 181 is set to about 1e16 to 5e17 (1/cm³), the density of the P− portion 183 is set to about 1e15 to 1e17 (1/cm³), the density of the anode 144 and the cathode 182 is set to about 1e20 (1/cm³), and the voltage applied between the N+ portion 181 and the anode 144 is adjusted, so that the electric field intensity in the avalanche region Zf may be set to 0.4 to 0.6 MV/cm.

Furthermore, the density of each of the P+ portion 141, the N+ portion 181, the P− portion 183, the cathode 182, and the anode 144, and a potential difference between the cathode 182 and the anode 144 are merely examples, and are not limited thereto.

### 6. Sixth Embodiment

Although the example in which the P− portion is formed in the hole of the annular portion 141a is described above, an N− portion including an N− type semiconductor region may be further formed on the P− portion.

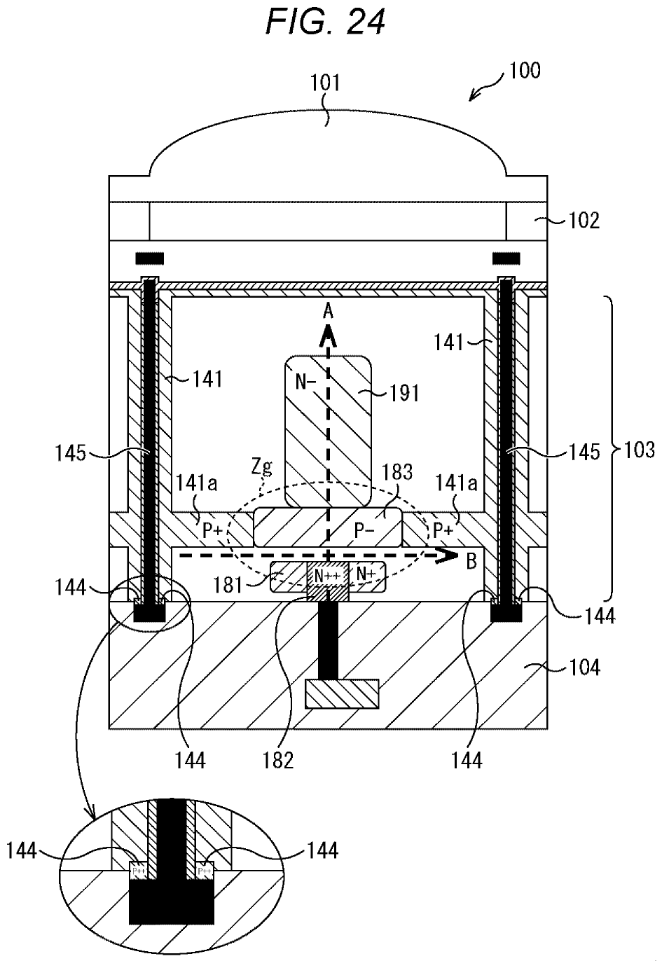

FIG. 24 illustrates an example of a pixel structure of a pixel 100 in which a P− portion is formed in the hole of the annular portion 141a in the pixel structure in FIG. 21, and an N− portion including N− (N− type semiconductor region) is further formed on the P− portion.

Note that, in the pixel structure in FIG. 24, components having the same functions as those of the pixel structure in FIG. 21 are denoted by the same reference signs, and the description thereof is omitted as appropriate.

The pixel structure in FIG. 24 is different from the pixel structure in FIG. 21 in providing the N− portion on the P− portion 183.

That is, the pixel structure in FIG. 24 is different from the pixel structure in FIG. 21 in further providing an N− portion 191.

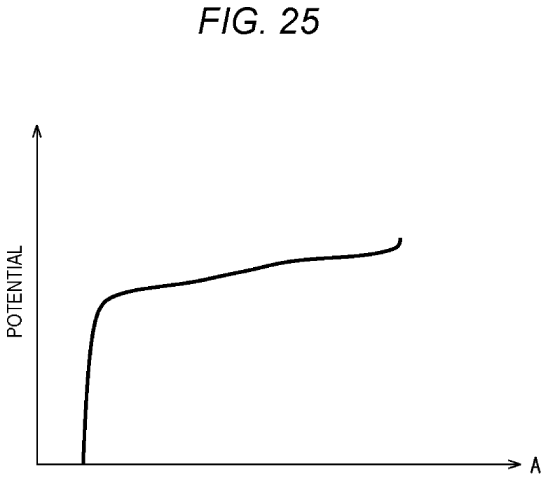

With such a structure, a potential distribution in an arrow A direction in the pixel structure in FIG. 24 is made the potential distribution that more smoothly changes with respect to a change in the arrow A direction than the potential distribution illustrated in FIG. 22 in which the potential barrier surrounded by the dotted line in FIG. 7 does not occur as illustrated in FIG. 25.

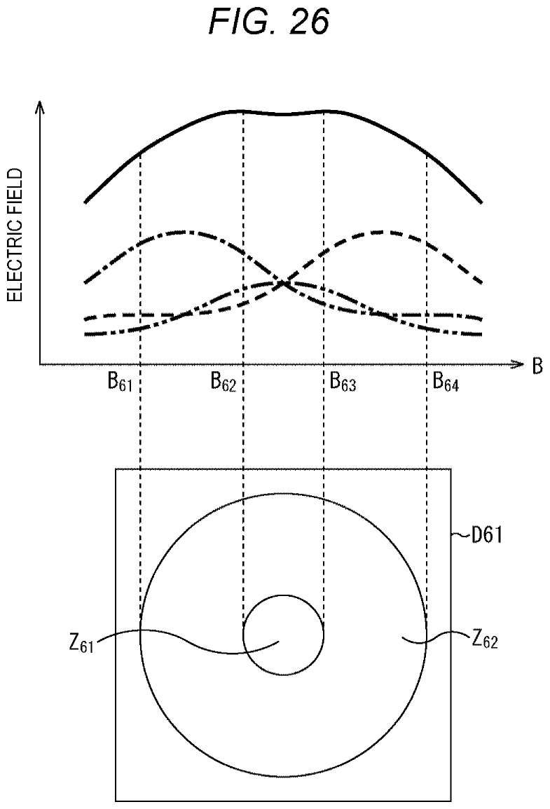

Furthermore, the N− portion 191 has a low density of, for example, about 5e14 to 5e15 (1/cm³), so that this does not affect an electric field. Therefore, the electric field intensity distribution in the pixel structure in FIG. 24 illustrated in FIG. 26 is similar to the electric field intensity distribution in FIG. 23.

As a result, an electric field intensity distribution in which a wide peak appears at the center position of the pixel 100 as indicated by a solid line in an upper part in FIG. 26 is formed.

That is, in the pixel structure of the pixel 100 in FIG. 23, as indicated by an electric field intensity distribution D61 when seen from an upper surface of the pixel 100 (when seen in an incident direction of incident light) in a lower part in FIG. 26, in a range Z62 corresponding to positions B61 to B64 in the upper part in FIG. 26, the electric field intensity is set to 0.4 to 0.6 MV/cm or higher with which the avalanche breakdown occurs, and there is a wide peak in a range Z61 corresponding to the positions B62 to B63 in the upper part in FIG. 26 in the vicinity of the center of the electric field intensity distribution D61 corresponding to the vicinity of the center of the pixel 100.

That is, in the pixel structure in FIG. 24, it is possible to form the range in which the electric field intensity is the highest in the vicinity of the center of the pixel 100 and cause the avalanche breakdown.

As a result, in the pixel 100 having the pixel structure in FIG. 24, the generation of the potential barrier is suppressed on the basis of the potential distribution as illustrated in FIG. 25 and the electric field intensity distribution as illustrated in FIG. 26, so that light-receiving sensitivity in a fine pixel 100 may be improved.

Note that, in a case in FIG. 24, for example, the density of the P+ portion 141 and the N+ portion 181 is set to about 1e16 to 5e17 (1/cm³), the density of the P− portion 183 is set to about 1e16 to 5e17 (1/cm³), the density of the N− portion 191 is set to about 5e14 to 5e15 (1/cm³), the density of the anode 144 and the cathode 182 is set to about 1e20 (1/cm³), and the voltage applied between the N+ portion 181 and the anode 144 is adjusted, so that the electric field intensity in the avalanche region Zg may be set to 0.4 to 0.6 MV/cm.

Furthermore, the density of each of the P+ portion 141, the N+ portion 181, the P− portion 183, the N− portion 191, the cathode 182, and the anode 144, and a potential difference between the cathode 182 and the anode 144 are merely examples, and are not limited thereto.

### 7. Seventh Embodiment

Although the example in which the anode 144 is formed at the surface position of the substrate 104 is described above, this may also be provided on a side surface of a boundary 145.

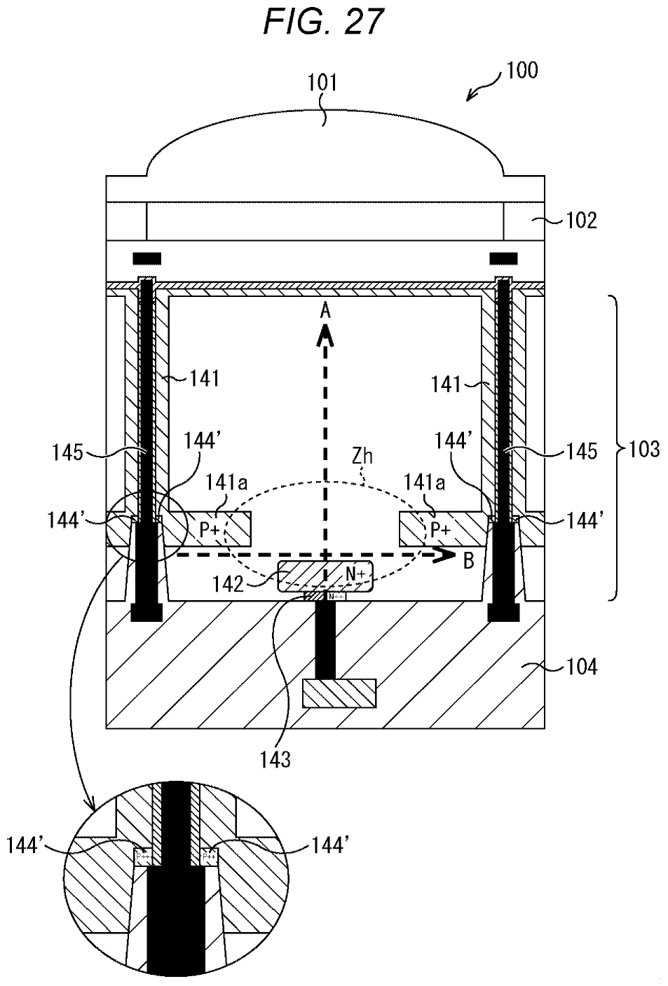

FIG. 27 illustrates an example of a pixel structure of a pixel 100 in which the anode 144 in the pixel structure in FIG. 9 is formed on the side surface of the boundary 145.

Note that, in the pixel structure in FIG. 27, components having the same functions as those of the pixel structure in FIG. 9 are denoted by the same reference signs, and the description thereof is omitted as appropriate.

The pixel structure in FIG. 27 is different from the pixel structure in FIG. 9 in providing an anode 144′ in place of the anode 144.

That is, the pixel structure in FIG. 27 is different from the pixel structure in FIG. 9 in providing the anode 144′ on the side surface of the boundary 145.

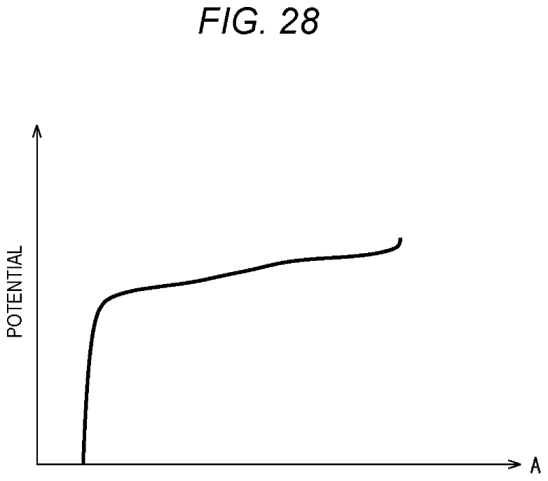

With such a structure also, a potential distribution in an arrow A direction in the pixel structure in FIG. 27 is made the potential distribution in which the potential barrier surrounded by the dotted line in FIG. 7 is not generated as is the case with the potential distribution illustrated in FIG. 10 as illustrated in FIG. 28.

Furthermore, as for the electric field intensity distribution also, as illustrated in FIG. 28, as is the case with the electric field intensity distribution illustrated in FIG. 11, by the fringe field formed between the annular portion 141a and the N+ portion 142, an electric field distribution formed between the annular portion 141a and the N+ portion 142 including an electric field distribution indicated by a dashed-dotted line and an electric field distribution indicated by a dotted line in FIG. 28 is synthesized, thereby forming the electric field intensity distribution having two peaks as indicated by a solid line in the upper part in FIG. 28.

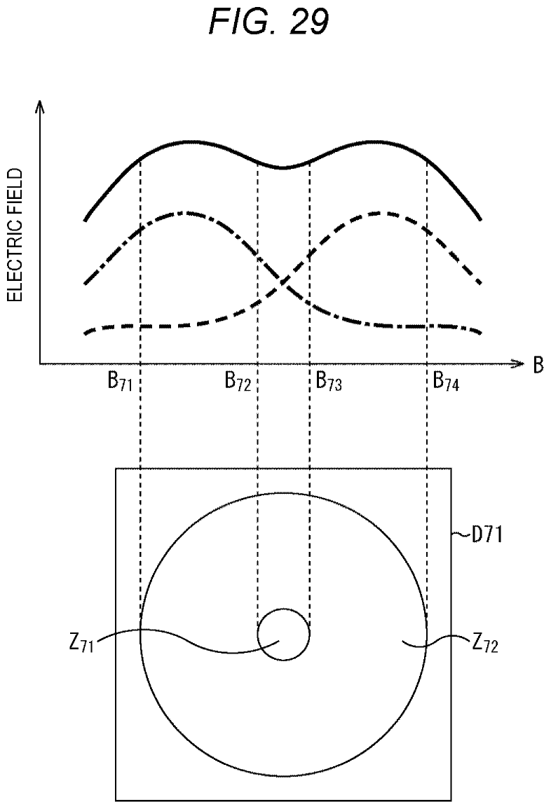

That is, in the pixel structure in FIG. 27 also, as indicated by an electric field intensity distribution D71 when seen from an upper surface of the pixel 100 (when seen in the incident direction of the incident light) in a lower part in FIG. 29, in a range Z72 corresponding to positions B71 to B74 in the upper part in FIG. 29, the electric field intensity is set to 0.4 to 0.6 MV/cm or higher with which the avalanche breakdown occurs, and in a range Z71 in the vicinity of the center of the electric field intensity distribution D71 corresponding to the vicinity of the center of the pixel 100, the electric field intensity is set lower than that in the range Z72, but is set to 0.4 MV/cm or higher with which the avalanche breakdown occurs.

That is, in the pixel structure in FIG. 27, as compared with the vicinity of the center of the pixel 100, a range in a peripheral portion thereof is formed as the range in which the electric field intensity is higher; however, the electric field intensity is 0.4 MV/cm or higher also in the range Z71 in the vicinity of the center, and the avalanche breakdown may be caused.

As a result, in the pixel 100 having the pixel structure in FIG. 27, the generation of the potential barrier is suppressed on the basis of the potential distribution as illustrated in FIG. 28 and the electric field intensity distribution as illustrated in FIG. 29, so that light-receiving sensitivity in a fine pixel 100 may be improved.

Note that, in a case in FIG. 27, for example, the density of the P+ portion 141 and the N+ portion 142 is set to about 1e16 to 5e17 (1/cm³), the density of the cathode 143 and the anode 144′ is set to about 1e20 (1/cm³), and the voltage applied between the cathode 143 and the anode 144 is adjusted, so that the electric field intensity in the avalanche region Zb may be set to 0.4 to 0.6 MV/cm.

Furthermore, the density of each of the P+ portion 141, the N+ portion 142, the cathode 143, and the anode 144′, and a potential difference between the cathode 143 and the anode 144′ are merely examples, and are not limited thereto.

### 8. Application Example to Electronic Device

The solid-state imaging element described above can be applied to various electronic devices such as, for example, an imaging device such as a digital still camera and a digital video camera, a mobile phone with an imaging function, or other devices having an imaging function.

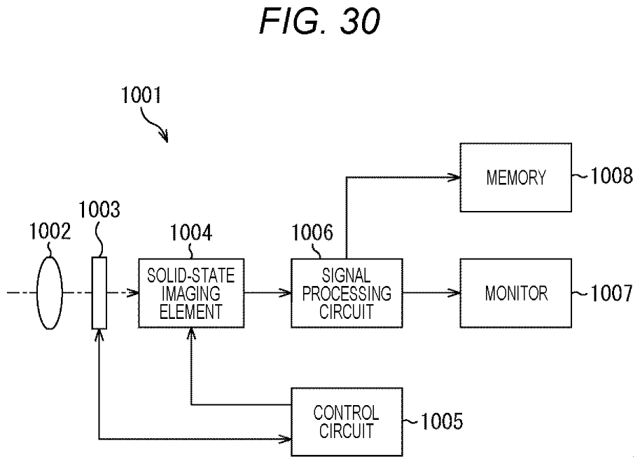

FIG. 30 is a block diagram illustrating a configuration example of the imaging device as the electronic device to which the present technology is applied.

An imaging device 1001 illustrated in FIG. 30 provided with an optical system 1002, a shutter device 1003, a solid-state imaging element 1004, a driving circuit 1005, a signal processing circuit 1006, a monitor 1007, and a memory 1008 may image a still image and a moving image.

The optical system 1002 including one or a plurality of lenses guides light from a subject (incident light) to the solid-state imaging element 1004 to form an image on a light-receiving surface of the solid-state imaging element 1004.

The shutter device 1003 arranged between the optical system 1002 and the solid-state imaging element 1004 controls a light application period to the solid-state imaging element 1004 and a light-shielding period according to control of the driving circuit 1005.

The solid-state imaging element 1004 includes a package including the above-described solid-state imaging element 11. The solid-state imaging element 1004 stores a signal charge for a certain period according to the light the image of which is formed on the light-receiving surface via the optical system 1002 and the shutter device 1003. The signal charge stored in the solid-state imaging element 1004 is transferred according to a driving signal (timing signal) supplied from the driving circuit 1005.

The driving circuit 1005 outputs the driving signal to control transfer operation of the solid-state imaging element 1004 and shutter operation of the shutter device 203 to drive the solid-state imaging element 1004 and the shutter device 1003.

The signal processing circuit 1006 performs various types of signal processing on the signal charge output from the solid-state imaging element 1004. The image (image data) obtained by the signal processing applied by the signal processing circuit 1006 is supplied to the monitor 1007 to be displayed or supplied to the memory 1008 to be stored (recorded).

Also in the imaging device 1001 configured as described above, by applying the above-described solid-state imaging element 11 in place of the above-described solid-state imaging element 1004, switching of FD conversion efficiency may be implemented in all the pixels.

### 9. Usage Example of Solid-State Imaging Element

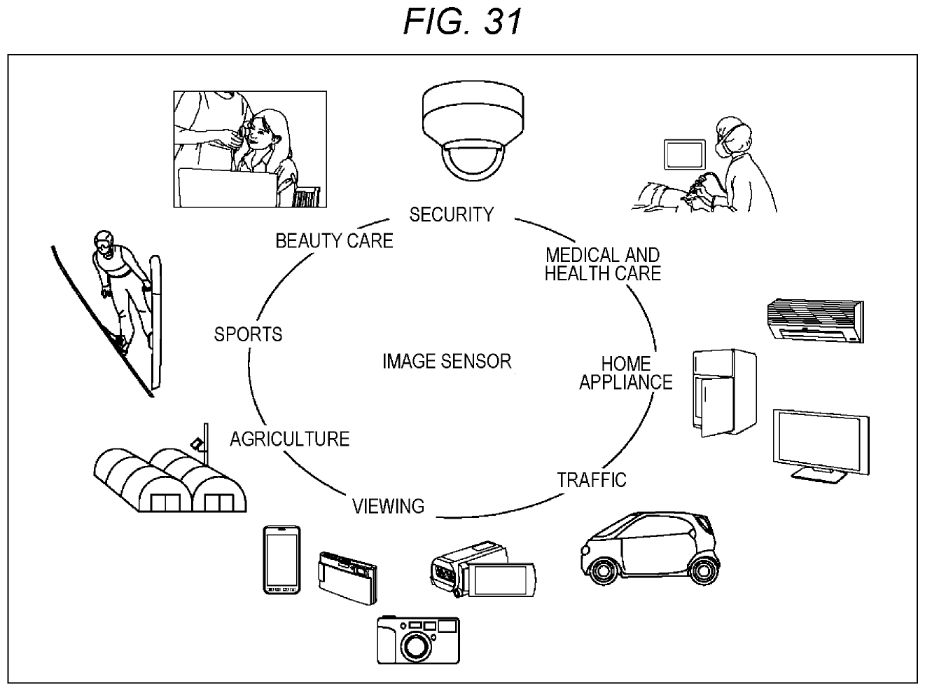

FIG. 31 is a diagram illustrating a usage example of using the above-described solid-state imaging element 11.

The above-described solid-state imaging element 11 may be used in various cases in which light such as visible light, infrared light, ultraviolet light, and X-ray is sensed as described below, for example.
A device that takes an image to be used for viewing such as a digital camera and a portable device with a camera function
A device for traffic purpose such as an in-vehicle sensor that takes images of the front, rear, surroundings, interior and the like of an automobile, a surveillance camera for monitoring traveling vehicles and roads, and a ranging sensor that measures a distance between vehicles and the like for safe driving such as automatic stop, recognition of a driver's condition and the like
A device for home appliance such as a television, a refrigerator, and an air conditioner that takes an image of a user's gesture and performs a device operation according to the gesture
A device for medical and health care use such as an endoscope and a device that performs angiography by receiving infrared light
A device for security use such as a security monitoring camera and an individual authentication camera
A device for beauty care such as a skin measuring device that images skin and a microscope that images scalp
A device for sporting use such as an action camera and a wearable camera for sporting use and the like
A device for agricultural use such as a camera for monitoring land and crop states

Note that, the present technology may also have a following configuration.

<1> A solid-state imaging element including:
an avalanche photodiode including an avalanche region including:
a semiconductor region of a first polarity connected to an anode; and
a semiconductor region of a second polarity connected to a cathode, in which
the semiconductor region of the first polarity has an annular structure with a hole at a center portion as seen in an incident direction of incident light, and
the semiconductor region of the second polarity is formed at a subsequent stage of a position of the hole of the annular structure in the incident direction of the incident light.

<2> The solid-state imaging element according to <1>, in which
the semiconductor region of the first polarity is a P+ type semiconductor region or an N+ type semiconductor region, and the semiconductor region of the second polarity is an N+ type semiconductor region or a P+ type semiconductor region.

<3> The solid-state imaging element according to <1>, in which
the semiconductor region of the second polarity is the cathode including a semiconductor with excessive impurities.

<4> The solid-state imaging element according to <3>, in which
the semiconductor region of the second polarity is the cathode including an N++ type semiconductor region or a P++ type semiconductor region.

<5> The solid-state imaging element according to <1>, in which
the semiconductor region of the first polarity is a P+ type semiconductor region or an N+ type semiconductor region, and the semiconductor region of the second polarity is a cathode including an N+ type semiconductor region and an N++ semiconductor region or a cathode including a P+ type semiconductor region and a P++ semiconductor region.

<6> The solid-state imaging element according to <5>, in which
in the semiconductor region of the second polarity, the N+ type semiconductor region is formed so as to surround the cathode including the N++ semiconductor region, or the P+ type semiconductor region is formed so as to surround the cathode including the P++ semiconductor region.

<7> The solid-state imaging element according to <1>, in which
a relationship between a diameter of the hole as seen in the incident direction and a diameter of the semiconductor region of the second polarity as seen in the incident direction is a relationship in which there is one peak of an electric field intensity distribution in the avalanche region.

<8> The solid-state imaging element according to <1>, in which
the semiconductor region of the first polarity is a P+ type semiconductor region or an N+ type semiconductor region, the semiconductor region of the second polarity is an N+ type semiconductor region or a P+ type semiconductor region, and a P− type semiconductor region or an N− semiconductor region is further formed in the hole.

<9> The solid-state imaging element according to <8>, in which
an N− type semiconductor region or a P− semiconductor region is further formed at a preceding stage of the hole.

<10> The solid-state imaging element according to any one of <1> to <9>, in which
the anode is formed on a surface of a substrate, embedded in the substrate, or formed on a side surface of a pixel boundary.

<11> An imaging device including:
a solid-state imaging element including:
an avalanche photodiode including an avalanche region including:
a semiconductor region of a first polarity connected to an anode; and
a semiconductor region of a second polarity connected to a cathode, in which
the semiconductor region of the first polarity has an annular structure with a hole at a center portion as seen in an incident direction of incident light, and
the semiconductor region of the second polarity is formed at a subsequent stage of a position of the hole of the annular structure in the incident direction of the incident light.

<12> An electronic device including:
a solid-state imaging element including:
an avalanche photodiode including an avalanche region including:
a semiconductor region of a first polarity connected to an anode; and
a semiconductor region of a second polarity connected to a cathode, in which
the semiconductor region of the first polarity has an annular structure with a hole at a center portion as seen in an incident direction of incident light, and
the semiconductor region of the second polarity is formed at a subsequent stage of a position of the hole of the annular structure in the incident direction of the incident light.

### REFERENCE SIGNS LIST

11 Solid-state imaging element
21 Pixel array unit
41 Pixel
101 On-chip lens
102 Color filter
103 Photoelectric conversion layer
104 Substrate
121 P+ portion
121a Annular portion
122 P+ portion
123 N+ portion
124 Cathode
125 Anode
126 Boundary
141 P+ portion
141a Annular portion
142 N+ portion
143 Cathode
144, 144′ Anode
145 Boundary
151 Cathode
161 N+ portion
162 Cathode
171 N+ portion
172 Cathode
181 N+ portion
182 Cathode
183 P− portion
191 N− portion

1. A solid-state imaging element comprising:
an avalanche photodiode including an avalanche region including:
a semiconductor region of a first polarity connected to an anode; and
a semiconductor region of a second polarity connected to a cathode, wherein
the semiconductor region of the first polarity has an annular structure with a hole at a center portion as seen in an incident direction of incident light, and
the semiconductor region of the second polarity is formed at a subsequent stage of a position of the hole of the annular structure in the incident direction of the incident light.

2. The solid-state imaging element according to claim 1, wherein
the semiconductor region of the first polarity is a P+ type semiconductor region or an N+ type semiconductor region, and the semiconductor region of the second polarity is an N+ type semiconductor region or a P+ type semiconductor region.

3. The solid-state imaging element according to claim 1, wherein
the semiconductor region of the second polarity is the cathode including a semiconductor with excessive impurities.

4. The solid-state imaging element according to claim 3, wherein
the semiconductor region of the second polarity is the cathode including an N++ type semiconductor region or a P++ type semiconductor region.

5. The solid-state imaging element according to claim 1, wherein
the semiconductor region of the first polarity is a P+ type semiconductor region or an N+ type semiconductor region, and the semiconductor region of the second polarity is a cathode including an N+ type semiconductor region and an N++ semiconductor region or a cathode including a P+ type semiconductor region and a P++ semiconductor region.

6. The solid-state imaging element according to claim 5, wherein
in the semiconductor region of the second polarity, the N+ type semiconductor region is formed so as to surround the cathode including the N++ semiconductor region, or the P+ type semiconductor region is formed so as to surround the cathode including the P++ semiconductor region.

7. The solid-state imaging element according to claim 1, wherein
a relationship between a diameter of the hole as seen in the incident direction and a diameter of the semiconductor region of the second polarity as seen in the incident direction is a relationship in which there is one peak of an electric field intensity distribution in the avalanche region.

8. The solid-state imaging element according to claim 1, wherein
the semiconductor region of the first polarity is a P+ type semiconductor region or an N+ type semiconductor region, the semiconductor region of the second polarity is an N+ type semiconductor region or a P+ type semiconductor region, and a P− type semiconductor region or an N− semiconductor region is further formed in the hole.

9. The solid-state imaging element according to claim 8, wherein
an N− type semiconductor region or a P− semiconductor region is further formed at a preceding stage of the hole.

10. The solid-state imaging element according to claim 1, wherein
the anode is formed on a surface of a substrate, embedded in the substrate, or formed on a side surface of a pixel boundary.

11. An imaging device comprising:
a solid-state imaging element including:
an avalanche photodiode including an avalanche region including:
a semiconductor region of a first polarity connected to an anode; and
a semiconductor region of a second polarity connected to a cathode, wherein
the semiconductor region of the first polarity has an annular structure with a hole at a center portion as seen in an incident direction of incident light, and
the semiconductor region of the second polarity is formed at a subsequent stage of a position of the hole of the annular structure in the incident direction of the incident light.

12. An electronic device comprising:
a solid-state imaging element including:
an avalanche photodiode including an avalanche region including:
a semiconductor region of a first polarity connected to an anode; and
a semiconductor region of a second polarity connected to a cathode, wherein
the semiconductor region of the first polarity has an annular structure with a hole at a center portion as seen in an incident direction of incident light, and
the semiconductor region of the second polarity is formed at a subsequent stage of a position of the hole of the annular structure in the incident direction of the incident light.
